(19) United States
(12) Patent Application Publication
(10) Pub. No.: US 2024/0301194 A1
(43) Pub. Date: Sep. 12, 2024

(54) FLUORINE-CONTAINING COMPOSITION AND PRODUCTION METHOD THEREFOR

(71) Applicant: DAIKIN INDUSTRIES, LTD., Osaka (JP)

(72) Inventors: Yuki SUZUKI, Osaka (JP); Makoto Matsuura, Osaka (JP); Yoshito Tanaka, Osaka (JP)

(73) Assignee: DAIKIN INDUSTRIES., LTD., Osaka (JP)

(21) Appl. No.: 18/658,511

(22) Filed: May 8, 2024

Related U.S. Application Data
(63) Continuation of application No. PCT/JP2022/041635, filed on Nov. 9, 2022.

(30) Foreign Application Priority Data
Nov. 12, 2021 (JP) 2021-184641

(51) Int. Cl. C08L 27/12; C09J 127/12; G02B 1/04; G02B 1/111; G03F 1/62

(52) U.S. Cl. CPC C08L 27/12; C09J 127/12; G03F 1/62; G02B 1/041; G02B 1/045; G02B 1/111

(57) ABSTRACT

A primary object of the present disclosure is to provide: a fluoropolymer composition that has a low refraction index and that comprises a structural unit having a fluorine-containing aliphatic ring, the fluorine-containing aliphatic ring having one, two, or three ethereal oxygen atoms as ring-constituting atoms; a production method therefor; and the like. The present disclosure relates to a fluorine-containing composition comprising two or more fluorine-containing polymers (A), each containing as a main component a structural unit having a fluorine-containing aliphatic ring, the fluorine-containing aliphatic ring having one, two, or three ethereal oxygen atoms as ring-constituting atoms; and the like.

### TECHNICAL FIELD

The present disclosure relates to a fluorine-containing composition comprising two or more fluorine-containing polymers, a method for producing the composition, and use of the composition, and the like.

### BACKGROUND ART

Fluoropolymers, which have a low refractive index, can be used, for example, for anti-reflection films and retardation films in liquid crystal displays or the like. Among the fluoropolymers, perfluoroamorphous polymers that have a structural unit containing a fluorine-containing aliphatic ring having an ethereal oxygen atom as a ring-constituting atom are expected to find application as various optical materials. For example, a fluorine-containing polymer having the following repeating units is expected to find application as a resin for plastic optical fibers by taking advantage of its low refractive index. However, there is a desire for an even lower refractive index.

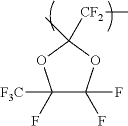

On the other hand, if the refractive index of a fluorine-containing polymer can be further reduced, it is expected to extend the application range of the fluorine-containing polymer. Patent Literature (PTL) 1 discloses that a copolymer containing two fluorine-containing aliphatic rings as structural units was obtained by copolymerizing perhalo-2,2-di-lower alkyl-1,3-dioxol and perfluoro-2-methylene-4-methyl-1,3-dioxolane with monomers.

### CITATION LIST

### Patent Literature

PTL 1: U.S. Pat. No. 3,468,524

### SUMMARY

The present disclosure includes, for example, the following.

A fluorine-containing composition comprising two or more fluorine-containing polymers (A),
the two or more fluorine-containing polymers (A) each containing as a main component a structural unit having a fluorine-containing aliphatic ring,
the fluorine-containing aliphatic ring having one, two, or three ethereal oxygen atoms as ring-constituting atoms.

### ADVANTAGEOUS EFFECTS

According to the present disclosure, a fluorine-containing polymer comprising a mixture of two or more fluorine-containing polymers is provided.

According to the present disclosure, a fluorine-containing polymer composition with a low refractive index can be provided.

According to the present disclosure, the ratio of fluorine-containing polymers in the fluorine-containing composition can be easily adjusted.

According to the present disclosure, a fluorine-containing composition comprising a mixture of two or more fluorine-containing polymers can be easily produced at low cost.

According to the present disclosure, a liquid composition in which two or more fluorine-containing polymers are dissolved in an aprotic solvent, and preferably dissolved in a high concentration in an aprotic solvent can be provided.

### DESCRIPTION OF EMBODIMENTS

The above summary of the present disclosure is not intended to describe each disclosed embodiment or every implementation of the present disclosure.

The following description of the present disclosure illustrates embodiments of examples in more detail.

In several places throughout the present disclosure, guidance is provided through lists of examples, and these examples can be used in various combinations.

In each instance, the described list serves only as a representative group, and should not be interpreted as an exclusive list.

All of the publications, patents, and patent applications cited herein are incorporated herein by reference in their entirety.

### Terms

Unless otherwise specified, the symbols and abbreviations in the present specification can be understood in the context of the present specification in the meanings commonly used in the technical field to which the present disclosure belongs.

In the present specification, the terms “comprising” and “containing” are used with the intention of including the terms “consisting essentially of” and “consisting of.”

Unless otherwise specified, the steps, treatments, or operations described in the present specification can be performed at room temperature.

In the present specification, room temperature can mean a temperature in the range of 10 to 40° C.

In the present specification, the phrase “Cn-Cm” (wherein n and m are each a number) indicates that the number of carbon atoms is n or more and m or less, as a person skilled in the art would generally understand.

Unless a person skilled in the art would specify otherwise, the compounds indicated in the present specification can include all stereoisomers (enantiomers, diastereomers, geometric isomers, etc.).

In the present specification, “refractive index” is determined in the following manner.

### Refractive Index

The refractive index of each sample at 23° C. is measured with a commercially available refractive index meter (typically an Abbe refractive index meter (NAR-1T SOLID), produced by Atago Co., Ltd.). The wavelength is a wavelength approximate to D-line because of the use of the LED attached to the device. Specifically, the refractive index is a value determined by the method described in a specific example of the present disclosure.

In this specification, “haze value” is determined in the following manner.

### Haze value

The haze value of each sample is measured using a commercially available haze value measuring instrument (typically a COH 7700 color spectrophotometer/haze meter, produced by Nippon Denshoku Industries Co., Ltd.). The samples were set to a size of 20 mm×20 mm and a thickness of 500 to 600 μm. Specifically, the haze is a value determined by the method described in a specific example of the present disclosure.

In the present specification, unless otherwise specified, the fluorine-containing aliphatic ring having one, two or three ethereal oxygen atoms as ring-constituting atoms” is an aliphatic ring having a plurality of carbon atoms and one, two, or three ethereal oxygen atoms as ring-constituting atoms, and containing one or more fluorine atoms. Preferably, oxygen atoms as ring-constituting atoms in the fluorine-containing aliphatic ring are not adjacent to each other. The number of oxygen atoms in the ring-constituting atoms is preferably 2.

The fluorine-containing aliphatic ring encompasses a saturated aliphatic monocyclic ring containing a fluorine atom.

The “fluorine-containing aliphatic ring” includes a ring of four or more members (e.g., a 4-membered ring, a 5-membered ring, a 6-membered ring, and a 7-membered ring). The 4-membered ring includes 1,3-dioxetane. The 5-membered ring includes 1,3-dioxolane. The 6-membered ring includes 1,3-dioxane, 1,4-dioxane, 1,3,5-trioxane. The 7-membered ring includes 1,3-dioxepane, 1,4-dioxepane and 1,3,5-trioxepane.

The fluorine-containing aliphatic ring may have at least one member selected from the group consisting of fluorine, perfluoroalkyl (e.g., C₁-C₅ linear or branched perfluoroalkyl) and perfluoroalkoxy (e.g., C₁-C₅ linear or branched perfluoroalkoxy) as a substituent. The number of substituents can be one or more, such as one to the maximum number of substitutions that can be made, 1 to 6, 1 to 5, 1 to 4, 1 to 3, 1 to 2, 1, 2, 3, or 4.

Examples of the “fluorine-containing aliphatic ring” includes perfluoro-1,3-dioxetane optionally having one or more substituents, perfluoro-1,3-dioxolane optionally having one or more substituents, perfluoro-1,3-dioxane optionally having one or more substituents, perfluoro-1,4-dioxane optionally having one or more substituents, perfluoro-1,3,5-trioxane optionally having one or more substituents, perfluoro-1,3-dioxane optionally having one or more substituent, perfluoro-1,4-dioxepane optionally having one or more substituents, and perfluoro-1,3,5-trioxepane optionally having one or more substituents.

In the present specification, unless otherwise specified, examples of “alkyl” include linear or branched C₁-C₁₀ alkyl, such as methyl, ethyl, propyl, isopropyl, butyl, isobutyl, sec-butyl, tert-butyl, pentyl, isopentyl, neopentyl, hexyl, heptyl, octyl, nonyl, and decyl.

In the present specification, unless otherwise specified, “fluoroalkyl” is alkyl in which at least one hydrogen atom is replaced by a fluorine atom. “Fluoroalkyl” can be linear or branched fluoroalkyl.

The number of carbon atoms in “fluoroalkyl” can be, for example, 1 to 12, 1 to 6, 1 to 5, 1 to 4, 1 to 3, 6, 5, 4, 3, 2, or 1.

The number of fluorine atoms in “fluoroalkyl” may be 1 or more (e.g., 1 to 3, 1 to 5, 1 to 9, 1 to 11, or 1 to the maximum number of substitutions that can be made.

“Fluoroalkyl” includes perfluoroalkyl. “Perfluoroalkyl” is an alkyl group in which all of the hydrogen atoms are replaced by fluorine atoms.

Examples of perfluoroalkyl include trifluoromethyl (CF₃—), pentafluoroethyl (C₂F₅—), heptafluoropropyl (CF₃CF₂CF₂—), and heptafluoroisopropyl ((CF₃)₂CF—).

Specific examples of “fluoroalkyl” include monofluoromethyl, difluoromethyl, trifluoromethyl (CF₃—), 2,2,2-trifluoroethyl, perfluoroethyl (C₂F₅—), tetrafluoropropyl (e.g., HCF₂CF₂CH₂—), hexafluoropropyl (e.g., (CF₃)₂CH—), perfluorobutyl (e.g., CF₃CF₂CF₂CF₂—), octafluoropentyl (e.g., HCF₂CF₂CF₂CF₂CH₂—), perfluoropentyl (e.g., CF₃CF₂CF₂CF₂CF₂—), perfluorohexyl (e.g., CF₃CF₂CF₂CF₂CF₂CF₂—), and the like.

In the present specification, unless otherwise specified, “alkoxy” may be a group represented by RO—, wherein R is alkyl (e.g., C₁₋₁₀ alkyl).

Examples of “alkoxy” include linear or branched C₁-C₁₀ alkoxy, such as methoxy, ethoxy, propoxy, isopropoxy, butoxy, isobutoxy, sec-butoxy, tert-butoxy, pentyloxy, isopentyloxy, neopentyloxy, hexyloxy, heptyloxy, octyloxy, nonyloxy, and decyloxy.

In the present specification, unless otherwise specified, “fluoroalkoxy” is an alkoxy group in which at least one hydrogen atom is replaced by a fluorine atom. “Fluoroalkoxy” can be linear or branched fluoroalkoxy.

The number of carbon atoms in “fluoroalkoxy” can be, for example, 1 to 12, 1 to 6, 1 to 5, 1 to 4, 1 to 3, 6, 5, 4, 3, 2, or 1.

The number of fluorine atoms in “fluoroalkoxy” can be 1 or more (e.g., 1 to 3, 1 to 5, 1 to 9, 1 to 11, or 1 to the maximum number of substituents that can be made).

“Fluoroalkoxy” includes perfluoroalkoxy. “Perfluoroalkoxy” is an alkoxy group in which all of the hydrogen atoms are replaced by fluorine atoms.

Examples of “perfluoroalkoxy” include trifluoromethoxy, pentafluoroethoxy, heptafluoropropoxy, and heptafluoroisopropoxy.

Specific examples of “fluoroalkoxy” include fluoromethoxy, difluoromethoxy, trifluoromethoxy, pentafluoroethoxy, heptafluoropropoxy (e.g., CF₃CF₂CF₂O—, (CF₃)₂CFO—), nonafluorobutoxy (e.g., CF₃CF₂CF₂CF₂O—, (CF₃)₃CO—), and the like.

### Fluorine-Containing Composition

A first embodiment of the present disclosure is a fluorine-containing composition comprising two or more fluorine-containing polymers (A), the two or more fluorine-containing polymers (A) each containing as a main component a structural unit having a fluorine-containing aliphatic ring, the fluorine-containing aliphatic ring having one, two, or three ethereal oxygen atoms as ring-constituting atoms.

So far there has been no report that a fluorine-containing polymer containing a structural unit represented by formula (A1) (which may be referred to herein as “structural unit (A1)”) as a main component (which may be referred to herein as a “fluorine-containing polymer (A1)”) and a fluorine-containing polymer that contains a structural unit represented by formula (A2) (which may be referred to herein as “structural unit (A2)”) as a main component (which may be referred to herein as a “fluorine-containing polymer (A2)”) are uniformly mixed. Adjusting the composition ratio of the structural units in the copolymer containing structural unit (A1) and structural unit (A2) was not easy, which made it difficult and expensive to produce a copolymer having a desired refractive index.

The fluorine-containing composition comprises two or more fluorine-containing polymers (A). The fluorine-containing polymers (A) contained in the composition are in a mixed state. The degree of mixing (mixed state) can be determined by measuring the haze of the fluorine-containing composition. Since a low degree of mixing may result in cloudiness, the composition is preferably mixed to the degree that the composition is not cloudy.

The haze value, which indicates the degree of mixing, can be, for example, 90 or less, or 70 or less, preferably 60 or less, and more preferably 55 or less. When the haze value is within these ranges, two or more fluorine-containing polymers are more uniformly mixed, which is advantageous for suppressing cloudiness of the fluorine-containing composition.

### Fluorine-Containing Polymer (A)

The fluorine-containing polymer (A) comprises as a main component a structural unit having a fluorine-containing aliphatic ring. The phrase “comprises as a main component a structural unit” means that the proportion of this structural unit in all of the structural units in the fluorine-containing polymer (A) is 50 mol % or more. The proportion is, for example, 51 mol % or more, or 60 mol % or more, preferably 80 mol % or more, more preferably 90 mol % or more, and particularly preferably 100 mol %. The fluorine-containing polymer (A) includes a homopolymer of a structural unit having a fluorinated aliphatic ring.

The structural unit having a fluorine-containing aliphatic ring in the fluorine-containing polymer (A) may be one or more types of structural units having a fluorine-containing aliphatic ring, preferably one to three types, more preferably one or two types, and particularly preferably one type of structural unit.

The fluorine-containing aliphatic ring has one, two, or three ethereal oxygen atoms as a ring-constituting atom. Preferably, the ethereal oxygen atoms are not adjacent to each other.

The fluorine-containing aliphatic ring can contain two or more (e.g., two, three, or four) carbon atoms as ring-constituting atoms and can contain one or more (e.g., one, two, three, four, five, or six) carbon-carbon bonds formed between adjacent carbon atoms.

The fluorine-containing aliphatic ring preferably contains two or more carbon atoms and one, two, or three oxygen atoms as ring-constituting atoms and contains no other atoms.

The fluorine-containing aliphatic ring preferably contains no hydrogen atoms.

The fluorine-containing aliphatic ring is preferably an aliphatic ring in which all of the hydrogen atoms are replaced by fluorine atoms.

The fluorine-containing aliphatic ring can be a 4-, 5-, 6-, or 7-membered ring. From the viewpoint of various physical properties of the fluorine-containing polymer (A), the fluorine-containing aliphatic ring is preferably a 4-, 5-, or 6-membered ring, and more preferably a 5-or 6-membered ring, and even more preferably a 5-membered ring.

The fluorine-containing aliphatic 4-membered ring can contain two carbon atoms and two oxygen atoms as ring-constituting atoms. Examples of the fluorine-containing aliphatic 4-membered ring include a perfluoro-1,3-dioxetane ring.

The fluorine-containing aliphatic 5-membered ring may contain four carbon atoms and one oxygen atom as ring-constituting atoms, or may contain three carbon atoms and two oxygen atoms as ring-constituting atoms. The fluorine-containing aliphatic 5-membered ring preferably contains three carbon atoms and two oxygen atoms. Examples of the fluorine-containing aliphatic 5-membered ring include a perfluoro-1,3-dioxolane ring and a perfluorooxolane ring.

The fluorine-containing aliphatic 6-membered ring may contain five carbon atoms and one oxygen atom as ring-constituting atoms, may contain four carbon atoms and two oxygen atoms as ring-constituting atoms, may contain three carbon atoms and three oxygen atoms as ring-constituting atoms, and preferably contains four carbon atoms and two oxygen atoms as ring-constituting atoms. Examples of the fluorine-containing aliphatic 6-membered ring include perfluoro-1,3-dioxane ring, perfluoro-1,4-dioxane ring, and perfluoro-1,3,5-trioxane ring.

The fluorine-containing aliphatic 7-membered ring may contain six carbon atoms and one oxygen atom as ring-constituting atoms, may contain five carbon atoms and two oxygen atoms as ring-constituting atoms, may contain four carbon atoms and three oxygen atoms as ring-constituting atoms, and may contain five carbon atoms and two oxygen atoms as ring-constituting atoms. Examples of the fluorine-containing aliphatic 7-membered ring include a perfluoro-1,3-dioxepane ring, a perfluoro-1,4-dioxepane ring, and a perfluoro-1,3,5-trioxepane ring.

The fluorine-containing aliphatic ring optionally has at least one substituent. When the fluorine-containing aliphatic ring has a plurality of substituents, the substituents may be the same or different.

The substituent can be at least one member selected from the group consisting of fluorine, perfluoroalkyl (e.g., linear or branched C₁-C₅ perfluoroalkyl), and perfluoroalkoxy (e.g., linear or branched C₁-C₅ perfluoroalkoxy). The number of substituents may be one or more, such as one to eight, one to seven, one to six, one to five, one to four, one to three, one to two, one, two, three, or four.

The substituent is preferably at least one member selected from the group consisting of fluorine, trifluoromethyl, perfluoroethyl, perfluoropropyl, perfluoroisopropyl, trifluoromethoxy, and perfluoroethoxy, more preferably at least one member selected from the group consisting of fluorine, trifluoromethyl, perfluoroethyl, perfluoropropyl, and perfluoroisopropyl, and particularly preferably at least one member selected from the group consisting of fluorine, trifluoromethyl, perfluoroethyl, and trifluoromethoxy.

The structural unit containing the fluorine-containing aliphatic ring may contain one or two perfluoroalkylene groups in addition to the fluorine-containing aliphatic ring. Such perfluoroalkylene groups are bound to ring-constituting carbon atoms of the fluorine-containing aliphatic ring to form a main chain of the fluorine-containing polymer (A).

Examples of such perfluoroalkylene groups are alkylene groups represented by —(CF₂)ₙ— (wherein n is an integer of 1 to 4).

An example of such perfluoroalkylene groups is —CF₂— that is other than the perfluoromethylene group constituting a dioxolane ring in a structural unit represented by the following formula (A2-1):

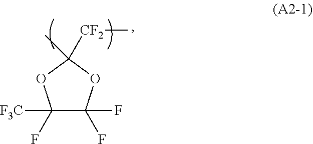

i.e., one —CF₂— not constituting the ring. The number of perfluoroalkylene groups not on the fluorine-containing aliphatic ring, i.e., exocyclic perfluoroalkylene groups in the structural unit may be two. When two such perfluoroalkylene groups are contained, the perfluoroalkylene groups may be the same or different.

The exocyclic perfluoroalkylene group contained in the structural unit having a fluorine-containing aliphatic ring may have one or more perfluoroalkoxy groups or perfluoroalkyl groups as substituents. When the exocyclic perfluoroalkylene group has multiple substituents, the substituents may be the same or different. The number of substituents may be one to the maximum number of substitutions that can be made, such as one to four, one to three, one to two, one, two, three, or four.

The substituent is preferably at least one group selected from the group consisting of trifluoromethyl, pentafluoroethyl, heptafluoropropyl, and heptafluoroisopropyl, and more preferably at least one group selected from the group consisting of trifluoromethyl and pentafluoroethyl.

The structural unit containing the fluorine-containing aliphatic ring may contain structural units (A1) and (A2). The structural units (A1) and (A2) may be present singly or in a combination of two or more in the fluorine-containing polymer.

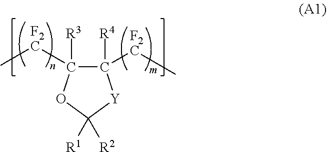

wherein n and m are independently 0 or 1, Y is an oxygen atom or CF₂, and R¹ to R⁴ independently represent fluorine, C₁-C₅ perfluoroalkyl, or C₁-C₅ perfluoroalkoxy.

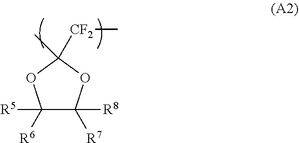

wherein R⁵ to R⁸ each independently represent fluorine, C₁-C₅ perfluoroalkyl, or C₁-C₅ perfluoroalkoxy.

In the structural unit (A1), n is 0 or 1, and preferably 0.

In the structural unit (A1), m is 0 or 1, and preferably 0.

In the structural unit (A1), Y is an oxygen atom or CF₂ and is preferably an oxygen atom.

In structural unit (A1), R¹ to R⁴ can independently represent a fluorine atom, a C₁-C₃ linear or branched perfluoroalkyl group, or a C₁-C₃ linear or branched perfluoroalkoxy group. Preferably, R¹ to R⁴ are each independently a fluorine atom, trifluoromethyl, pentafluoroethyl, or trifluoromethoxy. More preferably, R¹ to R⁴ are each independently a fluorine atom, trifluoromethyl, or trifluoromethoxy.

The structural unit (A1) is preferably a structural unit represented by formula (A1) wherein R¹ and R² each independently represent a fluorine atom or trifluoromethyl, and R³ and R⁴ each independently represent a fluorine atom, trifluoromethyl, or trifluoromethoxy.

The structural unit (A1) is more preferably a structural unit represented by formula (A1), wherein R¹ and R² independently represent a fluorine atom or trifluoromethyl, R³ represents a fluorine atom, and R⁴ represents fluorine, trifluoromethyl, or trifluoromethoxy.

The structural unit (A2) is particularly preferably a structural unit represented by formula (A2), wherein R¹ and R² are the same and represent a fluorine atom or trifluoromethyl, R³ represents a fluorine atom, and R⁴ represents a fluorine atom or trifluoromethoxy.

The structural unit (A1) includes a structural unit represented by the following formula (A1′) (which may be referred to herein as “structural unit (A1′)”).

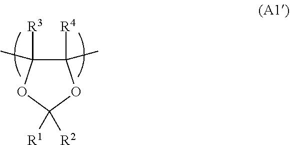

(wherein R¹ to R⁴ each independently represent a fluorine atom, a C₁-C₅ perfluoroalkyl group, or a C₁-C₅ perfluoroalkoxy group).

Preferable examples of structural units (A1) and (A1′) include structural units represented by formula (A1-1) below (which may be referred to herein as “structural unit (A1-1)”) and structural units represented by formula (A1-2) below (which may be referred to herein as “structural unit (A1-2)”).

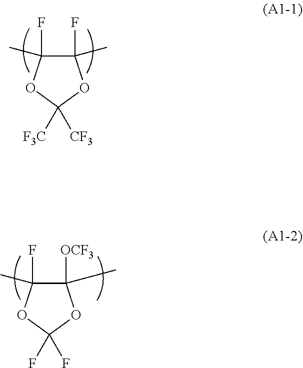

In structural unit (A2), R⁵ to R⁸ can independently represent a fluorine atom, a C₁-C₃ linear or branched perfluoroalkyl group, or a C₁-C₃ linear or branched perfluoroalkoxy group. Preferably, R⁵ to R⁸ are each independently a fluorine atom, trifluoromethyl, perfluoroethyl, or trifluoromethoxy. More preferably, R⁵ to R⁸ are each independently a fluorine atom, trifluoromethyl, or trifluoromethoxy.

The structural unit (A2) is preferably a structural unit represented by formula (A2) wherein R⁵ to R⁸ each independently represent a fluorine atom or trifluoromethyl.

The structural unit (A2) is more preferably a structural unit represented by formula (A2), wherein R⁵ to R⁸ represent a fluorine atom, or R⁵ represents trifluoromethyl and R⁶ to R⁸ represent a fluorine atom, or R⁵ and R⁸ both represent trifluoromethoxy and R⁶ and R⁷ represent a fluorine atom.

Preferable examples of the structural unit (A2) include structural units represented by formula (A2-1) below (which may be referred to herein as “structural unit (A2-1)”) and structural units represented by formula (A2-2) below (which may be referred to herein as “structural unit (A2-2)”).

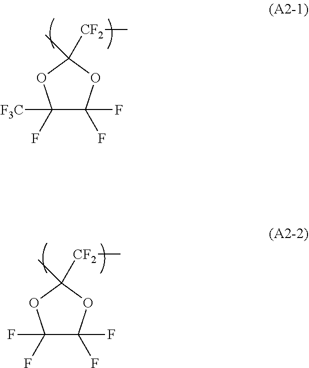

The fluorine-containing polymer (A) may contain other structural units in addition to the structural unit containing the fluorine-containing aliphatic ring contained as the main component. The proportion of such other structural units in all of the structural units in the fluorine-containing polymer (A) can be, for example, 50 mol % or less, 49 mol % or less, or 40 mol % or less.

When the fluorine-containing polymer (A) contains the structural unit (A1) as a main component, the proportion of the structural unit (A1) in all of the structural units in the fluorine-containing polymer (A) can be preferably 60 to 95 mol %, more preferably 60 to 90 mols, and even more preferably 65 to 85 mol %. When the fluorine-containing polymer (A) may comprise other structural units in addition to the structural unit (A1), the proportion of such other structural units in all of the structural units can be preferably 5 to 40 mol %, more preferably 10 to 40 mol %, and even more preferably 15 to 35 mol %.

When the fluorine-containing polymer (A) contains the structural unit (A2) as a main component, the proportion of the structural unit (A2) in all of the structural units in the fluorine-containing polymer (A) can be preferably 80 mol % or more, more preferably 90 mol % or more, even more preferably 95 mol %, and particularly preferably 100%. When the fluorine-containing polymer (A) comprises other structural units in addition to the structural unit (A2), the proportion of such other structural units in all of the structural units can be preferably 20 mol % or less, more preferably 10 mol % or less, and even more preferably 5 mol % or less.

Examples of such other structural units include, but are not limited to, a structural unit represented by the following formula (B):

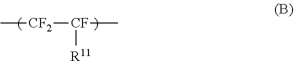

wherein R¹¹ represents fluorine, C₁-C₆ perfluoroalkyl, or C₁-C₆ perfluoroalkoxy (which may be referred to herein as “structural unit (B)”).

For example, the fluorine-containing polymer (A) may contain the structural unit (A1-1) as a main component and further contain the structural unit represented by the following formula (B-1):

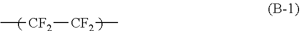

(which may be referred to herein as “structural unit (B-1)”).

R¹¹ can independently represent fluorine, C₁-C₆ linear or branched perfluoroalkyl, C₁-C₆ linear or branched perfluoroalkoxy.

Preferably, R¹¹ is fluorine, linear or branched C₁-C₄ perfluoroalkyl, or C₁-C₄ linear or branched perfluoroalkoxy.

More preferably, R¹¹ is fluorine, linear or branched C₁-C₃ perfluoroalkyl, or C₁-C₃ linear or branched perfluoroalkoxy.

Particularly preferably, R¹¹ is fluorine or trifluoroalkoxy.

The fluorine-containing polymers (A) contained in the fluorine-containing composition of the present disclosure may be
(1) at least two members selected from the fluorine-containing polymers (A1),
(2) at least two members selected from the fluorine-containing polymers (A2), or
(3) at least one member selected from the fluorine-containing polymers (A1) and at least one member selected from the fluorine-containing polymers (A2).

The fluorine-containing polymers (A) contained in the fluorine-containing composition of present disclosure are preferably at least one member selected from the fluorine-containing polymers (A1) and at least one member selected from the fluorine-containing polymers (A2); and more preferably at least one member selected from the fluorine-containing polymers (A1′) and at least one member selected from the fluorine-containing polymers (A2).

Examples of the fluorine-containing polymer (A1) include a copolymer containing as a main component a structural unit (A1-1) obtained by polymerization of tetrafluoroethylene and 2,2-bis(trifluoromethyl)-4,5-difluoro-1,3-dioxol and further containing a structural unit (B-1) (e.g., Teflon® AF copolymer); and a copolymer containing as a main component a structural unit (A1-2) obtained by polymerization of tetrafluoroethylene and 2,2,4-trifluoro-5-trifluoromethoxy-1,3-dioxol and further containing a structural unit (B-1) (e.g., Hyflon® AD); and the like. The fluorine-containing polymer (A1) is preferably a copolymer containing a structural unit (A1-1) as a main component and further containing a structural unit (B-1).

Specific examples of the fluorine-containing polymer (A2) include a polymer containing structural units (A2-1) as a main component and a polymer containing structural units (A2-2) as a main component. The fluorine-containing polymer (A2) is preferably a homopolymer composed of structural units (A2-1) and a homopolymer composed of structural units (A2-2).

The two or more fluorine-containing polymers (A) contained in the fluorine-containing composition of present disclosure are preferably at least two members selected from the group consisting of: copolymers containing structural units (A1-1) as a main component and further containing structural units (B) (preferably structural units (B-1)); copolymers containing structural units (A1-2) as a main component and further containing structural units (B) (preferably structural units (B-1)); homopolymers composed of structural units (A2-1); and homopolymers composed of structural units (A2-2).

The two or more fluorine-containing polymers (A) contained in the fluorine-containing composition of present disclosure are preferably a combination of at least one member selected from the group consisting of copolymers containing structural units (A1-1) as a main component and further containing structural units (B-1), and copolymers containing structural units (A1-2) as a main component and further containing structural units (B-1), and at least one member selected from the group consisting of homopolymers composed of structural units (A2-1), and homopolymers composed of structural units (A2-2).

The mass average molecular weight of the fluorine-containing polymer (A) may be, for example, within the range of 5000 to 1000000, preferably 10000 to 750000, more preferably 40000 to 500000, and particularly preferably 70000 to 350000.

The mass average molecular weight of the fluorine-containing polymer (A) is a value determined by a gel permeation chromatography (GPC) method (preferably the GPC method described in the Examples).

In the composition according to the present disclosure, the content of the fluorine-containing polymer (A) can be 70 mass % or more based on the mass of the composition. The content of the fluorine-containing polymer (A) can be preferably 80 mass % or more, more preferably 90 mass % or more, and particularly preferably 95 mass % or more.

The content of each fluorine-containing polymer (A) based on the total content of the fluorine-containing polymers (A) in the fluorine-containing composition of present disclosure can be selected according to the refractive index etc. required of the fluorine-containing composition. The content of each fluorine-containing polymer (A) can be, for example, 1 to 99 parts by mass, 5 to 95 parts by mass, 10 to 90 parts by mass, 15 to 85 parts by mass, 20 to 80 parts by mass, 30 to 70 parts by mass, or 40 to 60 parts by mass, based on the total content of the fluorine-containing polymers (A) taken as 100 parts by mass.

When the fluorine-containing composition of present disclosure contains a fluorine-containing polymer (A1) and a fluorine-containing polymer (A2), the content of the fluorine-containing polymer (A1) can be, for example, 1 to 50 parts by mass, 2 to 50 parts by mass, 5 to 50 parts by mass, 5 to 45 parts by mass, 5 to 40 parts by mass, 5 to 30 parts by mass, 10 to 50 parts by mass, 10 to 45 parts by mass, 10 to 40 parts by mass, or 10 to 30 parts by mass, preferably 5 to 45 parts by mass, and more preferably 5 to 40 parts by mass, based on the total content of the fluorine-containing polymers (A1) and (A2) taken as 100 parts by mass.

The fluorine-containing polymer (A) can be synthesized by a known method. For example, the fluorine-containing polymer (A) can be synthesized by polymerizing a monomer corresponding to the structural unit of the fluorine-containing polymer, optionally in the presence of a polymerization initiator. The polymerization method can be, for example, radical polymerization, bulk polymerization, solution polymerization, suspension polymerization, or emulsion polymerization.

A person skilled in the art would be able to appropriately select a monomer corresponding to the structural unit according to the structure of the structural unit. The monomers corresponding to the structural units (A1-1), (A1-2), (A2-1), (A2-2), and (B-1) are, for example, compounds represented by the following formulas (MA1-1), (MA1-2), (MA2-1), (MA2-2), and (MB-1), respectively (which may be referred to herein as “monomer (MA1-1),” “monomer (MA1-2),” “monomer (MA2-1),” “monomer (MA2-2),” and “monomer (MB-1),” respectively).

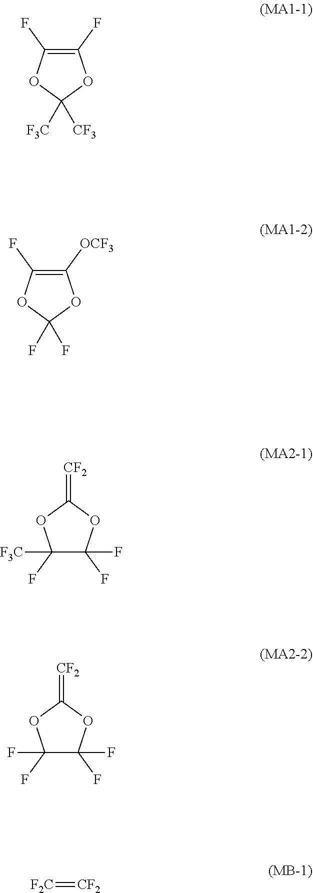

The fluoropolymer-containing composition of present disclosure may have a refractive index less than the sum of the values calculated by multiplying the individual refractive indices of two or more fluorine-containing polymers (A) contained in the composition by the mass ratio of the individual fluoropolymers (A) contained in the composition to the total mass of the fluorine-containing polymers (A) contained in the composition (which may be referred to herein as “the theoretical refractive index”). This means that, for example, a fluorine-containing composition containing 40 mass % of a fluorine-containing polymer (A) with a refractive index of 1.2 and 60 mass % of a fluorine-containing polymer (A) with a refractive index of 1.3 may have a refractive index lower than the value calculated by the following formula (1.26; theoretical refractive index).

$$( 1.2 \times 40 / 100 ) + ( 1.3 \times 60 / 100 ) = 1.26$$

The fluorine-containing composition of present disclosure being able to have a refractive index lower than the theoretical refractive index is an effect that could not be expected by a person skilled in the art. The refractive index of the fluorine-containing composition of present disclosure may be lower than the theoretical refractive index, for example, by 0.0005 or more, or 0.001 or more. The refractive index of the fluorine-containing composition of present disclosure may be lower than the theoretical refractive index, for example, by 0.0005 to 0.025, 0.0005 to 0.02, 0.0005 to 0.018, 0.001 to 0.025, 0.001 to 0.02, or 0.001 to 0.018.

The refractive index of the fluorine-containing composition may be lower than the largest of the individual refractive indices of the fluorine-containing polymers (A) contained in the composition, for example, by 0.005 or more, or 0.006 or more. The refractive index of the fluorine-containing composition may be lower than the largest of the individual refractive indices of fluorine-containing polymers (A) contained in the composition, and may be, for example, lower by 0.0005 to 0.025, 0.0005 to 0.02, 0.0005 to 0.018, 0.001 to 0.025, 0.001 to 0.02, or 0.001 to 0.018.

### Method for Producing the Fluorine-Containing Composition

One embodiment of the present disclosure is a method for producing a fluorine-containing composition comprising two or more fluorine-containing polymers (A) containing as a main component a structural unit having a fluorine-containing aliphatic ring. The fluorine-containing aliphatic ring has one, two, or three ethereal oxygen atoms as ring-constituting atoms. The method comprises mixing the two or more fluorine-containing polymers (A) in an aprotic solvent.

### Aprotic Solvent

The aprotic solvent is, for example, a fluorine-containing aprotic solvent. Examples of aprotic solvents include perfluoroaromatic compounds, perfluorotrialkylamines, perfluoroalkanes, hydrofluorocarbons, perfluorocyclic ethers, and hydrofluoroethers. Such aprotic solvents can be used alone or in a combination of two or more. The fluorine-containing polymer (A) is difficult to dissolve in solvents but can be dissolved in these solvents. The aprotic solvent is preferably at least one solvent selected from the group consisting of perfluoroaromatic compounds, hydrofluorocarbons, and hydrofluoroethers. The aprotic solvent is more preferably hydrofluoroether. The hydrofluoroether has strong ability to dissolve fluorine-containing polymers (A), in particular, fluorine-containing polymers (A2), and has a relatively low global warming potential (GWP).

The aprotic solvent (B) can have a global warming potential (GWP) of 600 or less, preferably 400 or less, and more preferably 300 or less.

The perfluoroaromatic compound is, for example, a perfluoroaromatic compound optionally having one or more perfluoroalkyl groups. The aromatic ring of the perfluoroaromatic compound may be at least one ring selected from the group consisting of a benzene ring, a naphthalene ring, and an anthracene ring. The perfluoroaromatic compound may have one or more (e.g., one, two, or three) aromatic rings.

The perfluoroalkyl group as a substituent is, for example, linear or branched C₁-C₆, C₁-C₅, or C₁-C₄ perfluoroalkyl, and preferably linear or branched C₁-C₃ perfluoroalkyl.

The number of substituents is, for example, one to four, preferably one to three, and more preferably one to two. When a plurality of substituents are present, they may be the same or different.

Examples of perfluoroaromatic compounds include perfluorobenzene, perfluorotoluene, perfluoroxylene, and perfluoronaphthalene.

Preferred examples of perfluoroaromatic compounds include perfluorobenzene and perfluorotoluene.

The perfluorotrialkylamine is, for example, an amine substituted with three linear or branched perfluoroalkyl groups. The number of carbon atoms of each perfluoroalkyl group is, for example, 1 to 10, preferably 1 to 5, and more preferably 1 to 4. The perfluoroalkyl groups may be the same or different, and are preferably the same.

Examples of perfluorotrialkylamines include perfluorotrimethylamine, perfluorotriethylamine, perfluorotripropylamine, perfluorotriisopropylamine, perfluorotributylamine, perfluorotri-sec-butylamine, perfluorotri-tert-butylamine, perfluorotripentylamine, perfluorotriisopentylamine, and perfluorotrineopentylamine.

Preferred examples of perfluorotrialkylamines include perfluorotripropylamine and perfluorotributylamine.

The perfluoroalkane is, for example, a linear, branched, or cyclic C₃-C₁₂ (preferably C₃-C₁₀, more preferably C₃-C₆) perfluoroalkane.

Examples of perfluoroalkanes include perfluoropentane, perfluoro-2-methylpentane, perfluorohexane, perfluoro-2-methylhexane, perfluoroheptane, perfluorooctane, perfluorononane, perfluorodecane, perfluorocyclohexane, perfluoro (methylcyclohexane), perfluoro (dimethylcyclohexane) (e.g., perfluoro (1,3-dimethylcyclohexane)), and perfluorodecalin.

Preferred examples of perfluoroalkanes include perfluoropentane, perfluorohexane, perfluoroheptane, and perfluorooctane.

The hydrofluorocarbon is, for example, a C₃-C₈ hydrofluorocarbon. Examples of hydrofluorocarbons include CF₃CH₂CF₂H, CF₃CH₂CF₂CH₃, CF₃CHFCHFC₂F₅, 1,1,2,2,3,3,4-heptafluorocyclopentane, CF₃CF₂CF₂CF₂CH₂CH₃, CF₃CF₂CF₂CF₂CF₂CHF₂, and CF₃CF₂CF₂CF₂CF₂CF₂CH₂CH₃.

Preferred examples of hydrofluorocarbons include CF₃CH₂CF₂H and CF₃CH₂CF₂CH₃.

The perfluorocyclic ether is, for example, a perfluorocyclic ether optionally having one or more perfluoroalkyl groups. The ring of the perfluorocyclic ether may be a 3-to 6-membered ring. The ring of the perfluorocyclic ether may have one or more oxygen atoms as a ring-constituting atom. The ring preferably has one or two oxygen atoms, and more preferably one oxygen atom.

The perfluoroalkyl group as a substituent is, for example, linear or branched C₁-C₆, C₁-C₅, or C₁-C₄ perfluoroalkyl. The perfluoroalkyl group is preferably linear or branched C₁-C₃ perfluoroalkyl.

The number of substituents is, for example, one to four, preferably one to three, and more preferably one to two. When a plurality of substituents are present, they may be the same or different.

Examples of perfluorocyclic ethers include perfluorotetrahydrofuran, perfluoro-5-methyltetrahydrofuran, perfluoro-5-ethyltetrahydrofuran, perfluoro-5-propyltetrahydrofuran, perfluoro-5-butyltetrahydrofuran, and perfluorotetrahydropyran.

Preferred examples of perfluorocyclic ethers include perfluoro-5-ethyltetrahydrofuran and perfluoro-5-butyltetrahydrofuran.

The hydrofluoroether may be, for example, at least one member selected from the group consisting of fluorine-containing ethers represented by formulas (C-1) to (C-4), (CF₃)₂CHOCH₃, (CF₃)₂CFOCH₃, CHF₂CF₂CH₂OCF₂CHF₂, CF₃CHFCF₂OCH₃, and CF₃CHFCF₂OCF₃.

F(CF₂)ₚO(CH₂)_{q}H (C-1)

(wherein p represents an integer of 1 to 6, and q represents an integer of 1 to 4);

H(CF₂)ₚO(CF₂)_{q}F (C-2)

(wherein p represents an integer of 1 to 6, and q represents an integer of 1 to 4);

H(CF₂)ₚO(CH₂)_{q}H (C-3)

(wherein p represents an integer of 1 to 6, and q represents an integer of 1 to 4); and

X(CF₂)ₚCH₂O(CF₂)_{q}H (C-4)

(wherein X represents a fluorine atom or a hydrogen atom, p represents an integer of 1 to 5, and q represents an integer of 1 to 4).

The hydrofluoroether is, for example, a compound represented by formula (3):

R³¹—O—R³² (3)

(wherein R³¹ is linear or branched propyl or butyl wherein at least one H is replaced by fluorine and R³² is methyl or ethyl).

The hydrofluoroether is, for example, at least one member selected from the group consisting of CF₃CF₂CF₂CF₂OCH₃, CF₃CF₂CF(CF₃)OCH₃, CF₃CF(CF₃)CF₂OCH₃, CF₃CF₂CF₂CF₂OC₂H₅, CF₃CH₂OCF₂CHF₂, C₂F₅CF(OCH₃)C₃F₇, (CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, CF₃CHFCF₂OCF₃, CF₃CF₂CF(CF₃)OC₂H₅, C₂F₅CF(OCH₃)CF₂CF₂CF₃, trifluoromethyl 1,2,2,2-tetrafluoroethyl ether (HFE-227me), difluoromethyl 1,1,2,2,2-pentafluoroethyl ether (HFE-227mc), trifluoromethyl 1,1,2,2-tetrafluoroethyl ether (HFE-227pc), difluoromethyl 2,2,2-trifluoroethyl ether (HFE-245mf), and 2,2-difluoroethyl trifluoromethyl ether (HFE-245pf).

Preferred examples of hydrofluoroethers include CF₃CF₂CF₂CF₂OCH₃, CF₃CF₂CF(CF₃)OCH₃, CF₃CF₂CF₂CF₂OCH₅, CF₃CF₂CF(CF₃)OCH₅, CF₃CH₂OCF₂CHF₂, C₂F₅CF(OCH₃)C₃F₇, (CF₃)₂CFOCH₃, CHF₂CF₂CH₂OCF₂CHF₂, CF₃CHFCF₂OCF₃, C₂F₅CF(OCH₃)CF₂CF₂CF₃, 1,1,2,3,3-hexafluoropropyl methyl ether (CF₃CHFCF₂OCH₃), 1,1,1,2,2-tetrafluoroethyl 2,2,2-trifluoroethyl ether (CHF₂CF₂OCH₂CF₃), and 1,1,1,3,3,3-hexafluoro-2-methoxypropane ((CF₃)₂CHOCH₃).

Examples of hydrofluoroethers include CF₃CF₂CF₂CF₂OCH₃, CF₃CF₂CF(CF₃)OCH₃, CF₃CF₂CF₂CF₂OCH₅, CF₃CF₂CF(CF₃)OC₂H₅, CF₃CH₂OCF₂CHF₂, C₂F₅CF(OCH₃)C₃F₇, (CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

The hydrofluoroether preferably has a global warming potential (GWP) of 600 or less, more preferably 400 or less, and particularly preferably 300 or less.

Two or more fluorine-containing polymers (A) as starting materials are dissolved in aprotic solvent and mixed. The dissolving and mixing methods are not limited and known methods can be applied. For example, after individually dissolving two or more fluorine-containing polymers (A) in an aprotic solvent, the obtained solutions can be mixed, or two or more fluorine-containing polymers may be added to an aprotic solvent all at once and dissolved and mixed, or each of them may be added, dissolved, and mixed sequentially. During the dissolution and mixing, stirring may be performed, if necessary. The temperature during the dissolution and mixing is not particularly limited as long as dissolution and mixing can be performed. The temperature can be, for example, 0° C. to 150° C., and preferably 40° C. to 120° C. The dissolution time and the mixing time can be appropriately set.

The amount of aprotic solvent used is not particularly limited as long as the fluorine-containing polymers (A) are dissolved therein. The amount of the aprotic solvent can be in the range of, for example, 100 to 5000 parts by mass, and preferably 300 to 1000 parts by mass, based on the total mass of the fluorine-containing polymers (A) taken as 100 parts by mass.

For example, by separating the solvent from the thus obtained solution containing two or more fluorine-containing polymers (A), a fluorine-containing composition having two or more fluorine-containing polymers (A) mixed therein can be obtained.

The method for separating the solvent can be, for example, drying, concentration, or re-precipitation (e.g., a method comprising drying after precipitation of the fluorine-containing composition).

### Use of the Fluorine-Containing Composition

The fluorine-containing composition can be used for applications in which fluorine-containing polymers (A) as starting materials is used. The fluorine-containing composition can have a refractive index that is lower than the refractive index calculated from the starting material fluorine-containing polymers (A) (theoretical refractive index). Therefore, the fluorine-containing composition can also be used for applications in which a lower refractive index is required as compared to that required in applications in which the starting material fluorine-containing polymers (A) are used.

The use of the fluorine-containing composition includes optical devices, anti-reflection films, lenses, pellicle films, sealants, and plastic optical fibers. The fluorine-containing composition of present disclosure can be used in place of fluorine-containing polymers that have been used in such applications. When the fluorine-containing composition is used as a thin film, the thin film can be produced by subjecting an aprotic solvent in which the starting material fluorine-containing polymers (A) are dissolved to drying, heating, or other means to remove the solvent.

The optical device of the present disclosure includes a fluorine-containing composition. An electret-wetting display or the like comprises an electrostatic dielectric conversion element. The electrostatic dielectric conversion element comprises an insulating film. As the insulating film, a fluorine-containing polymer is used. The fluorine-containing composition of present disclosure can be used as such a fluorine-containing polymer. Examples of such display devices include electronic paper displays, electronic noticeboards, electronic advertising, and electronic books.

The content of the fluorine-containing composition in the insulating film contained in the optical device of present disclosure can be, for example, 50 mass % to 100 mass %, preferably 60 mass % to 100 mass %, more preferably 80 mass % to 100 mass %, and particularly preferably 90 mass % to 100 mass %, based on the total mass of the insulating film.

The insulating film contained in the optical device of present disclosure contains at least a fluorine-containing composition and optionally further contains known components of insulating films used in electret materials, such as other resins, wetting agents, leveling agents, colorants, light diffusers, fillers, plasticizers, viscosity modifiers, flexibilizers, light-resistant stabilizers, reaction inhibitors, and adhesion promoters.

The anti-reflection film of the present disclosure comprises a fluorine-containing composition. To prevent reflections, an anti-reflection film is used in displays, such as liquid crystal displays. In the field of photoresists, an anti-reflection film is provided on a photoresist layer. The fluorine-containing composition of present disclosure, which has a low refractive index, can be suitably used as an anti-reflection film by forming the composition into a thin film.

The content of the fluorine-containing composition in the anti-reflection film of the present disclosure is, for example, 50 mass % to 100 mass %, preferably 60 mass % to 100 mass %, more preferably 80 mass % to 100 mass %, and particularly preferably 90 mass % to 100 mass %, based on the total mass of the anti-reflection film.

The anti-reflection film of the present disclosure comprieses at least one fluorine-containing composition and optionally further comprises known components used for anti-reflection films, such as other resins, colorants, light diffusers, various fillers (e.g., conductivity-imparting fillers), plasticizers, viscosity modifiers, flexibilizers, light-resistant stabilizers, reaction inhibitors, and adhesion promoters.

The lens of the present disclosure comprises a fluorine-containing composition. Lenses, such as optical lenses and eyeglass lenses, include those made of a fluorine-containing polymer. The fluorine-containing composition of present disclosure, which has a low refractive index, can be suitably used as such a fluorine-containing polymer.

The content of the fluorine-containing composition in the lens of present disclosure is, for example, 50 mass % to 100 mass %, preferably 60 mass % to 100 mass %, more preferably 80 mass % to 100 mass %, and particularly preferably 90 mass % to 100 mass %, based on the total mass of the lens.

The lens of the present disclosure comprises at least the fluorine-containing composition, and optionally further comprises known components used for lenses, such as other resins, colorants, light diffusers, various fillers (e.g., conductivity-imparting fillers), plasticizers, viscosity modifiers, flexibilizers, light-resistant stabilizers, reaction inhibitors, and adhesion promoters.

The pellicle film of the present disclosure comprises a fluorine-containing composition. The pellicle film used in the field of photomasks etc. include those made of a fluorine-containing polymer. The fluorine-containing composition of present disclosure, which has a low refractive index, can be suitably used as a fluorine-containing polymer for such pellicle films.

The content of the fluorine-containing composition in the pellicle film of present disclosure is, for example, 50 mass % to 100 mass %, preferably 60 mass % to 100 mass %, more preferably 80 mass % to 100 mass %, and particularly preferably 90 mass % to 100 masse, based on the total mass of the pellicle film.

The pellicle film of the present disclosure comprises at least a fluorine-containing composition, and optionally further comprises known components used for pellicle films, such as other resins, colorants, light diffusers, various fillers (e.g., conductivity-imparting fillers), plasticizers, viscosity modifiers, flexibilizers, light-resistant stabilizers, reaction inhibitors, and adhesion promoters.

The sealant of the present disclosure comprises a fluorine-containing composition. The fluorine-containing composition of present disclosure, which has a low refractive index, can be particularly suitably used as a fluorine-containing polymer for light emitting devices. For example, many light emitting element packages, such as light emitting diodes (LEDs), comprise at least a light emitting element, a dam, and a sealing body. The fluorine-containing composition of the present disclosure can be used as the sealing body.

The content of the fluorine-containing composition in the sealant of present disclosure is, for example, 50 mass % to 100 mass %, preferably 60 mass % to 100 mass %, more preferably 80 mass % to 100 mass %, and particularly preferably 90 mass % to 100 mass %, based on the total mass of the sealant.

The sealant of the present disclosure comprises at least a fluorine-containing composition, and optionally further comprises known components used for sealants, such as other resins, colorants, light diffusers, various fillers (e.g., conductivity-imparting fillers), plasticizers, viscosity modifiers, flexibilizers, light-resistant stabilizers, reaction inhibitors, and adhesion promoters.

The plastic optical fiber (POF) of the present disclosure comprises a fluorine-containing composition. Plastic optical fiber cladding includes those made of a fluorine-containing polymer. The fluorine-containing composition of present disclosure, which has a low refractive index, can be suitably used as a fluorine-containing polymer for use in cladding.

The content of the fluorine-containing composition in the plastic optical fiber cladding of present disclosure is, for example, 50 mass % to 100 mass %, preferably 60 mass % to 100 mass %, more preferably 80 mass % to 100 mass %, and particularly preferably 90 mass % to 100 mass, based on the total mass of the lens.

The plastic optical fiber cladding of the present disclosure comprises at least a fluorine-containing composition, and optionally further comprises known components used for cladding, such as other resins, colorants, light diffusers, fillers, plasticizers, viscosity modifiers, flexibilizers, light-resistant stabilizers, reaction inhibitors, and adhesion promoters.

### Composition Containing Two or More Fluorine-Containing Polymers (A) and Aprotic Solvent (Which May be Referred to Herein as “Composition (C)”)

In the composition (C), the fluorine-containing polymers (A) is a solution state in an aprotic solvent. The fluorine-containing composition can be obtained by drying the composition (C). Accordingly, unless otherwise specified, the explanations of the fluorine-containing composition, fluorine-containing polymers (A), aprotic solvent, etc., made above are applicable to the composition (C). Further, the composition (C) is also useful as a feedstock material for the fluorine-containing composition.

The total content of two or more fluorine-containing polymers (A) dissolved in an aprotic solvent in the composition (C) is, for example, 5 mass % to 65 mass %, 10 mass % to 65 mass %, 20 mass % to 65 mass %, 30 mass % to 65 mass %, 30 mass % and 65 mass %, and 20 mass % to 40 mass %, and preferably 20 mass % or more and 65 mass % or less, more preferably 25 mass % to 60 mass %, and particularly preferably 30 mass % to 50 mass %, based on the mass of the composition (C).

Although embodiments are described above, it can be understood that various modifications in form and details can be made without departing from the spirit and scope of the claims.

The present disclosure includes, for example, the following.

### Item 1

A fluorine-containing composition comprising two or more fluorine-containing polymers (A),
the two or more fluorine-containing polymers (A) each containing as a main component a structural unit having a fluorine-containing aliphatic ring,
the fluorine-containing aliphatic ring having one, two, or three ethereal oxygen atoms as ring-constituting atoms.

### Item 2

The fluorine-containing composition according to Item 1, wherein the composition has a refractive index that is less than the sum of values calculated by multiplying individual refractive indices of the fluorine-containing polymers (A) in the composition by individual mass ratios of the fluorine-containing polymers (A) in the composition to the total mass of the fluorine-containing polymers (A) in the composition.

### Item 3

The fluorine-containing composition according to Item 1 or 2, wherein the composition has a refractive index that is at least 0.005 less than the largest refractive index among the individual refractive indices of the fluorine-containing polymers (A) in the composition.

### Item 4

The fluorine-containing composition according to any one of Items 1 to 3, wherein the composition has a haze value of 90 or less.

### Item 5

The fluorine-containing composition according to any one of Items 1 to 4, wherein the composition has a haze value of 70 or less.

### Item 6

The fluorine-containing composition according to any one of Items 1 to 5, wherein the fluorine-containing polymers (A) contained in the composition are two or more members selected from the group consisting of
fluorine-containing polymers (A1) containing as a main component a structural unit represented by formula (A1):

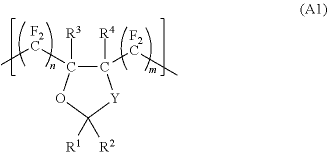

wherein n and m are each independently 0 or 1, Y is an oxygen atom or CF₂, and R¹ to R⁴ are each independently a fluorine atom, a C₁-C₅ perfluoroalkyl group, or a C₁-C₅ perfluoroalkoxy group and
fluorine-containing polymers (A2) containing as a main component a structural unit represented by formula (A2):

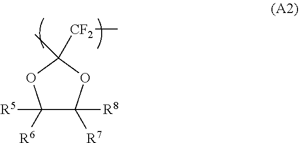

wherein R⁵ to R⁸ each represent a fluorine atom, a C₁-C₅ perfluoroalkyl group, or a C₁-C₅ perfluoroalkoxy group.

### Item 7

The fluorine-containing composition according to Item 6, wherein the fluorine-containing polymers (A1) are fluorine-containing polymers (A1′) containing as a main component a structural unit represented by formula (A1′):

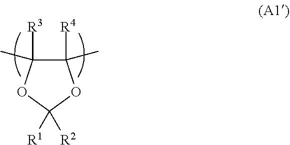

wherein R¹ to R⁴ each independently represent a fluorine atom, a C₁-C₅ perfluoroalkyl group, or a C₁-C₅ perfluoroalkoxy group.

### Item 8

The fluorine-containing composition according to Item 6 or 7, wherein the fluorine-containing polymers (A) in the composition are two or more members selected from the fluorine-containing polymers (A1).

### Item 9

The fluorine-containing composition according to Item 6, wherein the fluorine-containing polymers (A) in the composition are two or more members selected from the fluorine-containing polymers (A2).

### Item 10

The fluorine-containing composition according to Item 6 or 7, wherein the fluorine-containing polymers (A) contained in the composition are at least one member selected from the fluorine-containing polymers (A1) and at least one member selected from the fluorine-containing polymers (A2).

### Item 11

The fluorine-containing composition according to any one of Items 6 to 8 and 10, wherein the fluorine-containing polymers (A1) are at least one member selected from the group consisting of fluorine-containing polymers (A1-1) containing as a main component a structural unit represented by formula (A1-1):

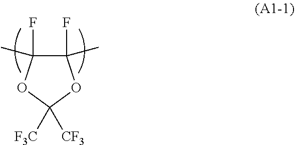

and fluorine-containing polymers (A1-2) containing as a main component a structural unit represented by formula (A1-2):

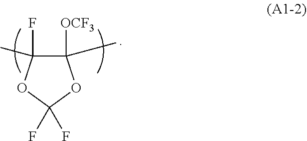

### Item 12

The fluorine-containing composition according to Item 6, 7, 9, or 10, wherein in the fluorine-containing polymers (A2), R⁵ to R⁸ each independently represent a fluorine atom, a trifluoromethyl group, or a trifluoroalkoxy group.

### Item 13

The fluorine-containing composition according to Item 6, 7, 9, 10, or 12, wherein the fluorine-containing polymers (A2) are at least one member selected from the group consisting of
fluorine-containing polymers (A2-1) containing as a main component a structural unit represented by formula (A2-1):

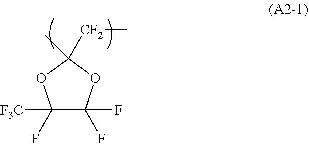

and
fluorine-containing polymers (A2-2) containing as a main component a structural unit represented by formula (A2-2):

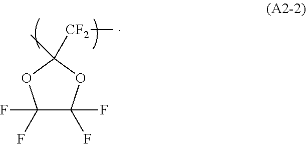

### Item 14

A composition comprising two or more fluorine-containing polymers (A) containing as a main component a structural unit having a fluorine-containing aliphatic ring and further containing an aprotic solvent,
the fluorine-containing polymers (A) being dissolved in the aprotic solvent,
the fluorine-containing aliphatic ring having one, two, or three ethereal oxygen atoms as ring-constituting atoms.

### Item 15

The composition according to Item 14, wherein a resin composition obtained by drying the composition to a solid has a refractive index that is less than the sum of values calculated by multiplying individual refractive indices of the fluorine-containing polymers (A) in the composition by individual mass ratios of the fluorine-containing polymers (A) in the composition to the total mass of the fluorine-containing polymers (A) in the composition.

### Item 16

The composition according to Item 14 or 15, wherein a resin composition obtained by drying the composition to a solid has a refractive index that is at least 0.005 less than the largest refractive index among the individual refractive indices of the fluorine-containing polymers (A) in the composition.

### Item 17

The composition according to any one of Items 14 to 16, wherein the aprotic solvent is at least one solvent selected from the group consisting of perfluoroaromatic compounds, perfluorotrialkylamines, perfluoroalkanes, hydrofluorocarbons, perfluorocyclic ethers, and hydrofluoroethers.

### Item 18

The composition according to any one of Items 14 to 17, wherein the aprotic solvent is a hydrofluoroether.

### Item 19

The composition according to any one of Items 14 to 18, wherein the aprotic solvent is at least one member selected from the group consisting of
a fluorine-containing ether represented by formula (C-1):

F(CF₂)ₚO(CH₂)_{q}H (C-1)

wherein p represents an integer of 1 to 6, and q represents an integer of 1 to 4,
a fluorine-containing ether represented by formula (C-2):

H(CF₂)ₚO(CF₂)_{q}F (C-2)

wherein p represents an integer of 1 to 6, and q represents an integer of 1 to 4,
a fluorine-containing ether represented by formula (C-3):

H(CF₂)ₚO(CH₂)_{q}H (C-3)

wherein p represents an integer of 1 to 6, and q represents an integer of 1 to 4,
a fluorine-containing ether represented by formula (C-4):

X(CF₂)ₚCH₂O(CF₂)_{q}H (C-4)

wherein X represents a fluorine atom or a hydrogen atom, p represents an integer of 1 to 5, and q represents an integer of 1 to 4,
(CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

### Item 20

The composition according to any one of Items 14 to 19, wherein the aprotic solvent is a compound represented by formula (3):

R³¹—O—R³² (3)

wherein R³¹ is linear or branched propyl or butyl with at least one H being replaced with fluorine, and
R³² is methyl or ethyl.

### Item 21

The composition according to any one of Items 14 to 20, wherein the aprotic solvent has a global warming potential (GWP) of 400 or less.

### Item 22

The composition according to any one of Items 14 to 19 and 21, wherein the aprotic solvent is at least one member selected from the group consisting of CF₃CF₂CF₂CF₂OCH₃, CF₃CF₂CF(CF₃)OCH₃, CF₃CF₂CF₂CF₂OC₂H₅, CF₃CF₂CF(CF₃)OC₂H₅, CF₃CH₂OCF₂CHF₂, C₂F₅CF(OCH₃)C₃F₇, (CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

### Item 23

The composition according to any one of Items 14 to 22, wherein the total content of the two or more fluorine-containing polymers (A) dissolved in the aprotic solvent is in the range of 20 mass % to 65 mass % based on the mass of the composition.

### Item 24

The composition according to any one of Items 14 to 23, wherein the fluorine-containing polymers (A) in the composition are two or more members selected from the group consisting of
fluorine-containing polymers (A1) containing as a main component a structural unit represented by formula (A1):

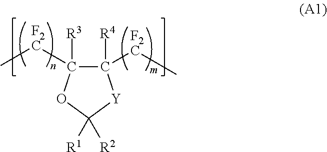

wherein n and m are each independently 0 or 1,
Y is an oxygen atom or CF2, and
R¹ to R⁴ independently represent a fluorine atom, a C₁-C₅ perfluoroalkyl group, or a C₁-C₅ perfluoroalkoxy group; and
fluorine-containing polymers (A2) containing as a main component a structural unit represented by formula (A2):

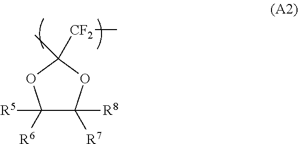

wherein R⁵ to R⁸ each independently represent a fluorine atom, a C₁-C₅ perfluoroalkyl group, or a C₁-C₅ perfluoroalkoxy group.

### Item 25

The composition according to Item 24, wherein the fluorine-containing polymers (A1) are fluorine-containing polymers (A1′) containing as a main component a structural unit represented by formula (A1′):

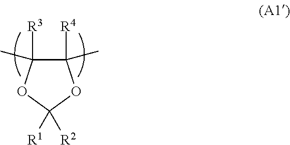

wherein R¹ to R⁴ each independently represent a fluorine atom, a C₁-C₅ perfluoroalkyl group, or a C₁-C₅ perfluoroalkoxy group.

### Item 26

The composition according to Item 24 or 25, wherein the fluorine-containing polymers (A) in the composition are two or more members selected from the fluorine-containing polymers (A1).

### Item 27

The composition according to Item 24, wherein the fluorine-containing polymers (A) in the composition are two or more members selected from the fluorine-containing polymers (A2).

### Item 28

The composition according to Item 24 or 25, wherein the fluorine-containing polymers (A) in the composition are at least one member selected from the fluorine-containing polymers (Al) and at least one member selected from the fluorine-containing polymers (A2).

### Item 29

The composition according to any one of Items 24 to 26 and 28, wherein the fluorine-containing polymers (A1) are at least one member selected from the group consisting of
fluorine-containing polymers (A1-1) containing as a main component a structural unit represented by formula (A1-1):

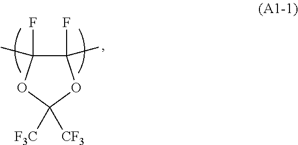

and
fluorine-containing polymers (A1-2) containing as a main component a structural unit represented by formula (A1-2):

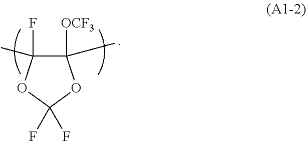

### Item 30

The composition according to Item 24, 25, 27, or 28, wherein in the fluorine-containing polymers (A2), R⁵ to R⁸ each independently represent a fluorine atom, a trifluoromethyl group, or a trifluoroalkoxy group.

### Item 31

The composition according to Item 24, 25, 27, 28, or 30, wherein the fluorine-containing polymers (A2) are at least one member selected from the group consisting of
fluorine-containing polymers (A2-1) containing as a main component a structural unit represented by formula (A2-1):

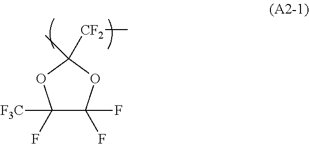

and
fluorine-containing polymers (A2-2) containing as a main component a structural unit represented by formula (A2-2)

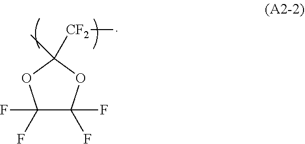

### Item 32

A method for producing a fluorine-containing composition comprising two or more fluorine-containing polymers (A) containing as a main component a structural unit having a fluorine-containing aliphatic ring, the method comprising mixing the two or more fluorine-containing polymers (A) in an aprotic solvent, the fluorine-containing aliphatic ring having one, two, or three ethereal oxygen atoms as ring-constituting atoms.

### Item 33

The method according to Item 32, wherein the aprotic solvent is at least one solvent selected from the group consisting of perfluoroaromatic compounds, perfluorotrialkylamines, perfluoroalkanes, hydrofluorocarbons, perfluorocyclic ethers, and hydrofluoroethers.

### Item 34

The method according to Item 32 or 33, wherein the aprotic solvent is a hydrofluoroether.

### Item 35

The method according to any one of Items 32 to 34, wherein the aprotic solvent is at least one member selected from the group consisting of
a fluorine-containing ether represented by formula (C-1):

F(CF₂)ₚO(CH₂)_{q}H (C-1)

wherein p represents an integer of 1 to 6, and q represents an integer of 1 to 4,
a fluorine-containing ether represented by formula (C-2):

H(CF₂)ₚO(CF₂)_{q}F (C-2)

wherein p represents an integer of 1 to 6, and q represents an integer of 1 to 4,
a fluorine-containing ether represented by formula (C-3):

H(CF₂)ₚO(CH₂)_{q}H (C-3)

wherein p represents an integer of 1 to 6, and q represents an integer of 1 to 4,
a fluorine-containing ether represented by formula (C-4):

X(CF₂)ₚCH₂O(CF₂)_{q}H (C-4)

wherein X represents a fluorine atom or a hydrogen atom, p represents an integer of 1 to 5, and q represents an integer of 1 to 4,
(CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

### Item 36

The method according to any one of Items 33 to 35, wherein the aprotic solvent is a compound represented by formula (3):

R³¹—O—R³² (3)

wherein R³¹ is linear or branched propyl or butyl with at least one H being replaced with fluorine and R³² is methyl or ethyl.

### Item 37

The method according to any one of Items 33 to 36, wherein the aprotic solvent has a global warming potential (GWP) of 400 or less.

### Item 38

The method according to any one of Items 33 to 35 and 37, wherein the aprotic solvent is at least one member selected from the group consisting of CF₃CF₂CF₂CF₂OCH₃, CF₃CF₂CF(CF₃)OCH₃, CF₃CF₂CF₂CF₂OC₂H₅, CF₃CF₂CF(CF₃)OC₂H₅, CF₃CH₂OCF₂CHF₂, C₂F₅CF(OCH₃)C₃F₇, (CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

### Item 39

The method according to any one of Items 33 to 38, wherein in the step of mixing the two or more fluorine-containing polymers (A) in the aprotic solvent, the aprotic solvent is used in an amount of 100 to 5000 parts by mass based on the total mass of the two or more fluorine-containing polymers (A) taken as 100 parts by mass.

### Item 40

The method according to any one of Items 33 to 39, wherein in the step of mixing the two or more fluorine-containing polymers (A) in the aprotic solvent, the aprotic solvent is used in an amount of 300 to 1000 parts by mass based on the total mass of the two or more fluorine-containing polymers (A) taken as 100 parts by mass.

### Item 41

The method according to any one of Items 33 to 40, wherein the fluorine-containing polymers (A) in the composition are two or more members selected from the group consisting of
fluorine-containing polymers (A1) containing as a main component a structural unit represented by formula (A1):

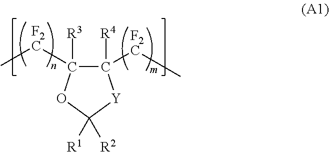

wherein n and m are each independently 0 or 1,
Y is an oxygen atom or CF₂, and
R¹ to R⁴ independently represent a fluorine atom, a C₁-C₅ perfluoroalkyl group, or a C₁-C₅ perfluoroalkoxy group and
fluorine-containing polymers (A2) containing as a main component a structural unit represented by formula (A2):

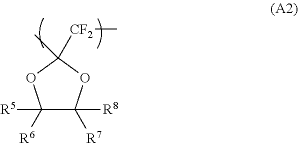

wherein R⁵ to R⁸ each independently represent a fluorine atom, a C₁-C₅ perfluoroalkyl group, or a C₁-C₅ perfluoroalkoxy group.

### Item 42

The method according to Item 41, wherein the fluorine-containing polymers (A1) are fluorine-containing polymers (A1′) containing as a main component a structural unit represented by formula (A1′):

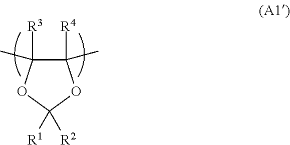

wherein R¹ to R⁴ each independently represent a fluorine atom, a C₁-C₅ perfluoroalkyl group, or a C₁-C₅ perfluoroalkoxy group.

### Item 43

The method according to Item 41 or 42, wherein the fluorine-containing polymers (A) in the composition are two or more members selected from the fluorine-containing polymers (A1).

### Item 44

The method according to Item 41, wherein the fluorine-containing polymers (A) in the composition are two or more members selected from the fluorine-containing polymers (A2).

### Item 45

The method according to Item 41 or 42, wherein the fluorine-containing polymers (A) in the composition are at least one member selected from the fluorine-containing polymers (A1) and at least one member selected from the fluorine-containing polymers (A2).

### Item 46

The method according to any one of Items 41 to 43 and 45, wherein the fluorine-containing polymers (A1) are at least one member selected from the group consisting of
fluorine-containing polymers (A1-1) containing as a main component a structural unit represented by formula (A1-1):

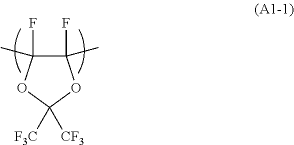

and
fluorine-containing polymers (A1-2) containing as a main component a structural unit represented by formula (A1-2):

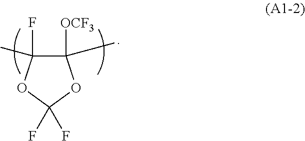

### Item 47

The method according to Item 41, 42, 44, or 45, wherein in the fluorine-containing polymers (A2), R⁵ to R⁸ each independently represent a fluorine atom, a trifluoromethyl group, or a trifluoroalkoxy group.

### Item 48

The method according to Item 41, 42, 44, 45, or 47, wherein the fluorine-containing polymers (A2) are at least one member selected from the group consisting of
fluorine-containing polymers (A2-1) containing as a main component a structural unit represented by formula (A2-1):

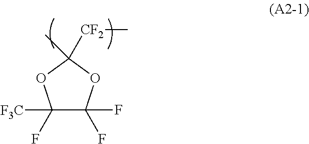

and
fluorine-containing polymers (A2-2) containing as a main component a structural unit represented by formula (A2-2):

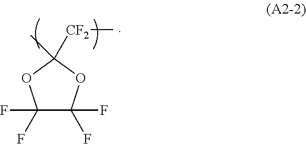

### Item 49

An optical device comprising the fluorine-containing composition of any one of Items 1 to 13.

### Item 50

An anti-reflective film comprising the fluorine-containing composition of any one of Items 1 to 13.

### Item 51

A lens comprising the fluorine-containing composition of any one of Items 1 to 13.

### Item 52

A pellicle membrane comprising the fluorine-containing composition of any one of Items 1 to 13.

### Item 53

A sealant comprising the fluorine-containing composition of any one of Items 1 to 13.

### Item 54

A plastic optical fiber comprising the fluorine-containing composition of any one of Items 1 to 13.

### EXAMPLES

An embodiment of the present disclosure is described in more detail below with reference to Examples; however, the present disclosure is not limited to these.

Teflon® AF copolymer is a copolymer containing a structural unit (A1-1) as a main component and further containing a structural unit (B-1). Hyflon® AD is a copolymer containing a structural unit (A1-2) as a main component and further containing a structural unit (B-1).

Novec 7100 is a mixed solution of methyl nonafluorobutyl ether and methyl nonafluoroisobutyl ether, produced by 3M Japan Limited.

### Refractive Index

The refractive index of sheet samples obtained in the Examples below was measured at 23° C. using an Abbe refractometer (NAR-1T SOLID) produced by Atago Co., Ltd. The wavelength was a wavelength approximate to D-line because of the use of the LED attached to the device.

### Haze Value

The haze value of the sheet samples obtained in the Examples below was measured using a COH 7700 color spectrophotometer/haze meter, produced by Nippon Denshoku Industries. Each sample had a size of 20 mm×20 mm and a thickness of 500 to 600 μm.

### Transparency

Each sample with a thickness of 0.5 mm was placed on a base material. When the base material could be visually recognized through the sample, the sample was evaluated as transparent.

### Comparative Example 1

After 1.5 g of a Teflon® AF copolymer and 3.5 g of a homopolymer of the structural unit (A2-1) were fully mixed in powder form in a plastic bag, the resulting composition was melted into a sheet at 270° C. Since the obtained sheet was cloudy (haze value: 95.7), the refractive index was not measured.

### Comparative Example 2

After 1.5 g of a Hyflon® AD copolymer and 3.5 g of a homopolymer of the structural unit (A2-1) were fully mixed in powder form in a plastic bag, the resulting composition was melted into a sheet at 270° C. Since the obtained sheet was cloudy (haze value: 96.9), the refractive index was not measured.

### Example 1

After 0.5 g of a Teflon® AF copolymer and 4.5 g of a homopolymer of the structural unit (A2-1) were dissolved in 45 g of Novec 7100 in a 100 mL polyethylene bottle, the resulting solution was slowly dried overnight at room temperature in saturated steam of Novec 7100 to obtain a colorless transparent (haze value: 17.5) fluorine-containing composition in the form of a sheet. The obtained sheet had a refractive index of 1.328.

### Example 2

After 1.5 g of a Teflon® AF copolymer and 3.5 g of a homopolymer of the structural unit (A2-1) were dissolved in 45 g of Novec 7100 in a 100 mL polyethylene bottle, the resulting solution was slowly dried overnight at room temperature in saturated steam of Novec 7100 to obtain a colorless transparent (haze value: 19.2) fluorine-containing composition in the form of a sheet. The obtained sheet had a refractive index of 1.318.

### Example 3

After 1.5 g of a Hyflon® AD copolymer and 3.5 g of a homopolymer of the structural unit (A2-1) were dissolved in 45 g of Novec 7100 in a 100 mL polyethylene bottle, the resulting solution was slowly dried overnight at room temperature in saturated steam of Novec 7100 to obtain a colorless transparent (haze value: 54.5) fluorine-containing composition in the form of a sheet. The obtained sheet had a refractive index of 1.317.

Table 1 shows the formulations of the compositions produced in the above Comparative Examples and Examples, refractive indices, etc. For reference, refractive indices of the polymers used as starting materials are also shown in Table 1. The theoretical refractive indices were calculated from the refractive indices and the content ratio of the polymers of each composition. By mixing the Teflon® AF copolymer or the Hyflon® AD copolymer with the homopolymer of the structural unit (A2-1), the refractive index of the homopolymer of the structural unit (A2-1) was successfully reduced.

TABLE 1

| | | | | | | | | Measured |
|---|---|---|---|---|---|---|---|---|
| | | | | | | | Theoretical | refractive |
| | Component 1 | | Component 2 | | Mixing | Mixed | refractive | index |
| Item | Component | mass % | Component | mass % | method | state | index | Component |
| Reference | Teflon ® AF | 100 | — | — | — | — | — | 1.307 |
| data | | | | | | | | |
| Reference | Hyflon ® AD | 100 | — | — | — | — | — | 1.327 |
| data | | | | | | | | |
| Reference | Homopolymer | 100 | — | — | — | — | — | 1.334 |
| data | of A2-1 | | | | | | | |
| Comparative | Teflon ® AF | 30 | Homopolymer | 70 | Powder | Cloudy | — | — |
| Example 1 | | | of A2-1 | | mixing | | | |
| Comparative | Hyflon ® AD | 30 | Homopolymer | 70 | Powder | Cloudy | — | — |
| Example 2 | | | of A2-1 | | mixing | | | |
| Example 1 | Teflon ® AF | 10 | Homopolymer | 90 | Solution | Colorless and | 1.331 | 1.328 |
| | | | of A2-1 | | mixing | transparent | | |
| Example 2 | Teflon ® AF | 30 | Homopolymer | 70 | Solution | Colorless and | 1.326 | 1.318 |
| | | | of A2-1 | | mixing | transparent | | |
| Example 3 | Hyflon ® AD | 30 | Homopolymer | 70 | Solution | Colorless and | 1.332 | 1.317 |
| | | | of A2-1 | | mixing | transparent | | |

1. A fluorine-containing composition comprising two or more fluorine-containing polymers (A),
the two or more fluorine-containing polymers (A) each containing as a main component a structural unit having a fluorine-containing aliphatic ring,
the fluorine-containing aliphatic ring having one, two, or three ethereal oxygen atoms as ring-constituting atoms.

2. The fluorine-containing composition according to claim 1, wherein the composition has a refractive index that is less than the sum of values calculated by multiplying individual refractive indices of the fluorine-containing polymers (A) in the composition by individual mass ratios of the fluorine-containing polymers (A) in the composition to the total mass of the fluorine-containing polymers (A) in the composition.

3. The fluorine-containing composition according to claim 1, wherein the composition has a refractive index that is at least 0.005 less than the largest refractive index among the individual refractive indices of the fluorine-containing polymers (A) in the composition.

4. The fluorine-containing composition according to claim 1, wherein the composition has a haze value of 90 or less.

5. (canceled)

6. The fluorine-containing composition according to claim 1, wherein the fluorine-containing polymers (A) contained in the composition are two or more members selected from the group consisting of
fluorine-containing polymers (A1) containing as a main component a structural unit represented by formula (A1): 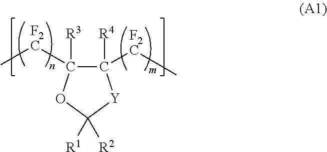
wherein n and m are each independently 0 or 1, Y is an oxygen atom or CF_{2,} and R¹ to R⁴ are each independently a fluorine atom, a C₁-C₅ perfluoroalkyl group, or a C₁-C₅ perfluoroalkoxy group and
fluorine-containing polymers (A2) containing as a main component a structural unit represented by formula (A2): 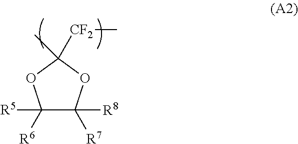
wherein R⁵ to R⁸ each represent a fluorine atom, a C₁-C₅ perfluoroalkyl group, or a C₁-C₅ perfluoroalkoxy group.

7. The fluorine-containing composition according to claim 6, wherein the fluorine-containing polymers (A1) are fluorine-containing polymers (A1′) containing as a main component a structural unit represented by formula (A1′): 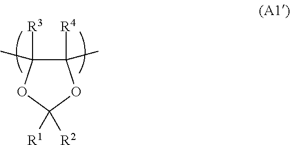
wherein R¹ to R⁴ each independently represent a fluorine atom, a C₁-C₅ perfluoroalkyl group, or a C₁-C₅ perfluoroalkoxy group.

8. The fluorine-containing composition according to claim 6, wherein the fluorine-containing polymers (A) in the composition are two or more members selected from the fluorine-containing polymers (A1).

9. The fluorine-containing composition according to claim 6, wherein the fluorine-containing polymers (A) in the composition are two or more members selected from the fluorine-containing polymers (A2).

10. The fluorine-containing composition according to claim 6, wherein the fluorine-containing polymers (A) contained in the composition are at least one member selected from the fluorine-containing polymers (A1) and at least one member selected from the fluorine-containing polymers (A2).

11. The fluorine-containing composition according to claim 6, wherein the fluorine-containing polymers (A1) are at least one member selected from the group consisting of fluorine-containing polymers (A1-1) containing as a main component a structural unit represented by formula (A1-1): 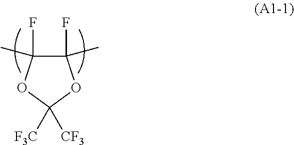
and fluorine-containing polymers (A1-2) containing as a main component a structural unit represented by formula (A1-2):

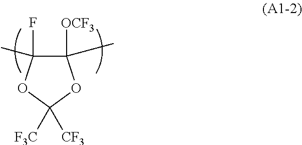

12. The fluorine-containing composition according to claim 6, wherein in the fluorine-containing polymers (A2), R⁵ to R⁸ each independently represent a fluorine atom, a trifluoromethyl group, a perfluoroethyl group, or a trifluoromethoxy group.

13. The fluorine-containing composition according to claim 6, wherein the fluorine-containing polymers (A2) are at least one member selected from the group consisting of
fluorine-containing polymers (A2-1) containing as a main component a structural unit represented by formula (A2-1): 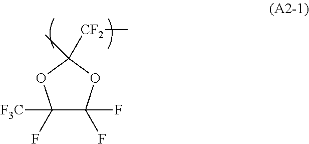
and
fluorine-containing polymers (A2-2) containing as a main component a structural unit represented by formula (A2-2):

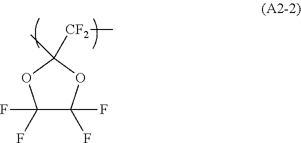

14. A composition comprising two or more fluorine-containing polymers (A) containing as a main component a structural unit having a fluorine-containing aliphatic ring and further containing an aprotic solvent,
the fluorine-containing polymers (A) being dissolved in the aprotic solvent,
the fluorine-containing aliphatic ring having one, two, or three ethereal oxygen atoms as ring-constituting atoms.

15. The composition according to claim 14, wherein a resin composition obtained by drying the composition to a solid has a refractive index that is less than the sum of values calculated by multiplying individual refractive indices of the fluorine-containing polymers (A) in the composition by individual mass ratios of the fluorine-containing polymers (A) in the composition to the total mass of the fluorine-containing polymers (A) in the composition.

16. The composition according to claim 14, wherein a resin composition obtained by drying the composition to a solid has a refractive index that is at least 0.005 less than the largest refractive index among the individual refractive indices of the fluorine-containing polymers (A) in the composition.

17. The composition according to claim 14, wherein the aprotic solvent is at least one solvent selected from the group consisting of perfluoroaromatic compounds, perfluorotrialkylamines, perfluoroalkanes, hydrofluorocarbons, perfluorocyclic ethers, and hydrofluoroethers.

18. The composition according to claim 14, wherein the aprotic solvent is a hydrofluoroether.

19.-21. (canceled)

22. The composition according to claim 14, wherein the aprotic solvent is at least one member selected from the group consisting of CF₃CF₂CF₂CF₂OCH₃, CF₃CF₂CF(CF₃)OCH₃, CF₃CF₂CF₂CF₂OC₂H₅, CF₃CF₂CF(CF₃)OC₂H₅, CF₃CH₂OCF₂CHF₂, C₂F₅CF(OCH₃)C₃F₇, (CF₃)₂CHOCH₃, (CF₃)₂CFOCH₃, CHF₂CF₂OCH₂CF₃, CHF₂CF₂CH₂OCF₂CHF₂, CF₃CHFCF₂OCH₃, and CF₃CHFCF₂OCF₃.

23. The composition according to claim 14, wherein the total content of the two or more fluorine-containing polymers (A) dissolved in the aprotic solvent is in the range of 20 mass % to 65 mass % based on the mass of the composition.

24. The composition according to claim 14, wherein the fluorine-containing polymers (A) in the composition are two or more members selected from the group consisting of
fluorine-containing polymers (A1) containing as a main component a structural unit represented by formula (A1): 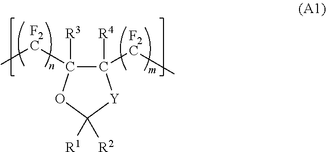
wherein n and m are each independently 0 or 1,
Y is an oxygen atom or CF₂, and
R¹ to R⁴ independently represent a fluorine atom, a C₁-C₅ perfluoroalkyl group, or a C₁-C₅ perfluoroalkoxy group; and
fluorine-containing polymers (A2) containing as a main component a structural unit represented by formula (A2): 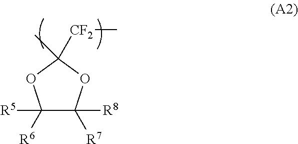
wherein R⁵ to R⁸ each independently represent a fluorine atom, a C₁-C₅ perfluoroalkyl group, or a C₁-C₅ perfluoroalkoxy group.

25. The composition according to claim 24, wherein the fluorine-containing polymers (A1) are fluorine-containing polymers (A1′) containing as a main component a structural unit represented by formula (A1′): 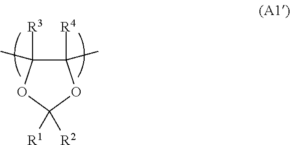
wherein R¹ to R⁴ each independently represent a fluorine atom, a C₁-C₅ perfluoroalkyl group, or a C₁-C₅ perfluoroalkoxy group.

26. The composition according to claim 24, wherein the fluorine-containing polymers (A) in the composition are two or more members selected from the fluorine-containing polymers (A1).

27. The composition according to claim 24, wherein the fluorine-containing polymers (A) in the composition are two or more members selected from the fluorine-containing polymers (A2).

28. The composition according to claim 24, wherein the fluorine-containing polymers (A) in the composition are at least one member selected from the fluorine-containing polymers (A1) and at least one member selected from the fluorine-containing polymers (A2).

29. The composition according to claim 24, wherein the fluorine-containing polymers (A1) are at least one member selected from the group consisting of
fluorine-containing polymers (A1-1) containing as a main component a structural unit represented by formula (A1-1): 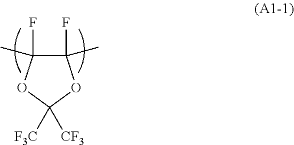
and
fluorine-containing polymers (A1-2) containing as a main component a structural unit represented by formula (A1-2):

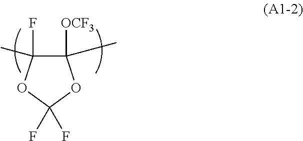

30. The composition according to claim 24, wherein in the fluorine-containing polymers (A2), R⁵ to R⁸ each independently represent a fluorine atom, a trifluoromethyl group, a perfluoroethyl group or a trifluoromethoxy group.

31. The composition according to claim 24, wherein the fluorine-containing polymers (A2) are at least one member selected from the group consisting of
fluorine-containing polymers (A2-1) containing as a main component a structural unit represented by formula (A2-1): 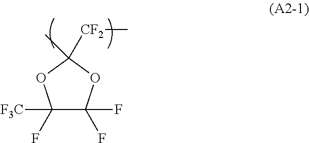
and
fluorine-containing polymers (A2-2) containing as a main component a structural unit represented by formula (A2-2)

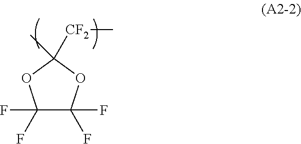

32. A method for producing a fluorine-containing composition comprising two or more fluorine-containing polymers (A) containing as a main component a structural unit having a fluorine-containing aliphatic ring, the method comprising mixing the two or more fluorine-containing polymers (A) in an aprotic solvent, the fluorine-containing aliphatic ring having one, two, or three ethereal oxygen atoms as ring-constituting atoms.

33. The method according to claim 32, wherein the aprotic solvent is at least one solvent selected from the group consisting of perfluoroaromatic compounds, perfluorotrialkylamines, perfluoroalkanes, hydrofluorocarbons, perfluorocyclic ethers, and hydrofluoroethers.

34. The method according to claim 32, wherein the aprotic solvent is a hydrofluoroether.

35.-38. (canceled)

39. The method according to claim 32, wherein in the step of mixing the two or more fluorine-containing polymers (A) in the aprotic solvent, the aprotic solvent is used in an amount of 100 to 5000 parts by mass based on the total mass of the two or more fluorine-containing polymers (A) taken as 100 parts by mass.

40. (canceled)

41. The method according to claim 32, wherein the fluorine-containing polymers (A) in the composition are two or more members selected from the group consisting of
fluorine-containing polymers (A1) containing as a main component a structural unit represented by formula (A1): 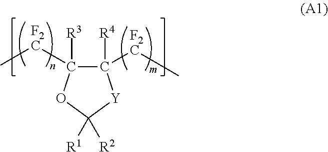
wherein n and m are each independently 0 or 1,
Y is an oxygen atom or CF₂, and
R¹ to R⁴ independently represent a fluorine atom, a C₁-C₅ perfluoroalkyl group, or a C₁-C₅ perfluoroalkoxy group
and
fluorine-containing polymers (A2) containing as a main component a structural unit represented by formula (A2): 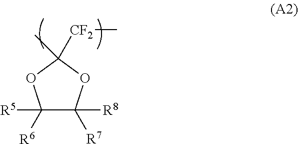
wherein R⁵ to R⁸ each independently represent a fluorine atom, a C₁-C₅ perfluoroalkyl group, or a C₁-C₅ perfluoroalkoxy group.

42. The method according to claim 41, wherein the fluorine-containing polymers (A1) are fluorine-containing polymers (A1′) containing as a main component a structural unit represented by formula (A1′): 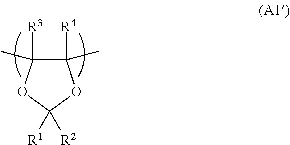
wherein R¹ to R⁴ each independently represent a fluorine atom, a C₁-C₅ perfluoroalkyl group, or a C₁-C₅ perfluoroalkoxy group.

43. The method according to claim 41, wherein the fluorine-containing polymers (A) in the composition are two or more members selected from the fluorine-containing polymers (A1).

44. The method according to claim 41, wherein the fluorine-containing polymers (A) in the composition are two or more members selected from the fluorine-containing polymers (A2).

45. The method according to claim 41, wherein the fluorine-containing polymers (A) in the composition are at least one member selected from the fluorine-containing polymers (A1) and at least one member selected from the fluorine-containing polymers (A2).

46. The method according to claim 41, wherein the fluorine-containing polymers (A1) are at least one member selected from the group consisting of
fluorine-containing polymers (A1-1) containing as a main component a structural unit represented by formula (A1-1): 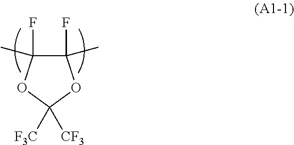
and
fluorine-containing polymers (A1-2) containing as a main component a structural unit represented by formula (A1-2):

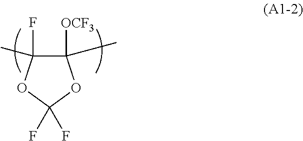

47. The method according to claim 41, wherein in the fluorine-containing polymers (A2), R⁵ to R⁸ each independently represent a fluorine atom, a trifluoromethyl group, a perfluoroethyl group or a trifluoromethoxy group.

48. The method according to claim 41, wherein the fluorine-containing polymers (A2) are at least one member selected from the group consisting of
fluorine-containing polymers (A2-1) containing as a main component a structural unit represented by formula (A2-1): 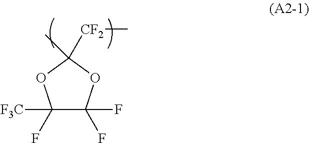
and
fluorine-containing polymers (A2-2) containing as a main component a structural unit represented by formula (A2-2):

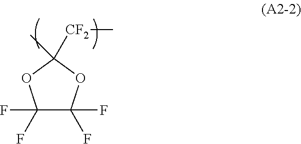

49. An optical device comprising the fluorine-containing composition of claim 1.

50. An anti-reflection film comprising the fluorine-containing composition of claim 1.

51. A lens comprising the fluorine-containing composition of claim 1.

52. A pellicle membrane comprising the fluorine-containing composition of claim 1.

53. A sealant comprising the fluorine-containing composition of claim 1.

54. A plastic optical fiber comprising the fluorine-containing composition of claim 1.
